(19) United States
(12) Patent Application Publication
(10) Pub. No.: US 2015/0118572 A1
(43) Pub. Date: Apr. 30, 2015

(54) SOLID-STATE BATTERY AND METHODS OF FABRICATION

(71) Applicant: BATTERY ENERGY STORAGE SYSTEMS-TECHNOLOGIES, Albany, NY (US)

(72) Inventors: Isaac Lund, Albany, NY (US); Fernando Gomez-Baquero, Albany, NY (US); Bruce Toyama, Saratoga Springs, NY (US)

(73) Assignee: BATTERY ENERGY STORAGE SYSTEMS-TECHNOLOGIES, Albany, NY (US)

(21) Appl. No.: 14/066,176

(22) Filed: Oct. 29, 2013

(51) Int. Cl. H01M 4/58; C30B 25/02; H01M 4/04; C30B 23/06; H01M 10/0525; H01M 10/0562

(52) U.S. Cl. CPC H01M 4/582; H01M 10/0525; H01M 10/0562; H01M 4/0459; H01M 4/0426; C30B 23/066; C30B 25/02; H01M 4/0404; H01M 4/0428; H01M 2300/0068
USPC 429/322; 429/231.95; 205/59; 204/192.17; 117/108; 117/104; 427/126.1; 427/123; 264/81

(57) ABSTRACT

The present disclosure generally provides for a solid-state battery, and methods of fabricating embodiments of the solid-state battery. Embodiments of the present disclosure may include an electrode for a solid-state battery, the electrode including: a current collector region including a conductive, lithium electroactive material; and a plurality of nanowires contacting the current collector region.

### BACKGROUND

Embodiments of the present disclosure relate generally to a solid-state battery. More specifically, the present disclosure relates to structures of a solid-state battery and respective methods of manufacture.

Generally, a battery is an electrochemical cell that stores and converts chemical energy from chemical oxidation and reduction reactions into useable electricity. Batteries contain two electrodes in which these reactions occur, typically with reduction reactions during discharge occurring in the “cathode” and the corresponding oxidation reactions occurring in the “anode.” These reactions are due in part to a difference in electrochemical potential between the materials of the anode and the cathode. In many ion-based batteries, the two electrodes are separated by an “electrolyte,” which is capable of conducting certain ions but is otherwise electrically insulative. In conventional batteries, the electrodes are each electrically connected to a conductive (e.g., metallic) material known as a current collector. Each of the two current collectors can be connected to the other using an external circuit that allows for electron transfer between the two electrodes. To equalize the potential difference, the anode releases ions (e.g., from oxidation) when electrons are allowed to flow through the external circuit. The flow of ions through the electrolyte balances the passage of electrons to the anode. The ions then react with the chemically reactive material of the cathode. The number of ions that a material can accept is known as the “specific capacity” of the material. Battery electrode materials influence the specific capacity of the battery, and are often, but not exclusively, defined in terms of the energy capacity per weight, for example in milliamp hours per gram (mAh/g).

A specific type of battery is a Lithium-ion battery, or Li-ion battery. Li-ion batteries transport Li ions between electrodes to charge and discharge the battery. A common type of Li-ion battery uses graphite as the anode (LiC₆ when charged, C otherwise), a lithiated transition metal oxide as the cathode (e.g., LiCoO₂, LiNiO₂, LiMn₂O₄), and a liquid electrolyte that is normally composed of a lithium salt ionized in a mixture of two or more carbonate solvents. Graphite anodes typically have reversible (rechargeable) capacities approximating 370 mAh/g, while the specific capacity of metal oxide or iron phosphate cathodes may be between approximately 140 mAh/g and approximately 280 mAh/g. Graphite anodes function by intercalation of Li ions between the components of the Li-ion battery. The electric potential of the battery partially depends on the difference in thermodynamic potential between the oxidation from the anode and the reduction in the cathode, which for example may be 3.2 V for a LiFePO₄ cathode and 4.2 V for a cathode composed of LiCoO₂. The overall capacity of the battery is defined as the battery's capacity for Li-ions in proportion to the overall weight, while the power density (a measure of power output) is the overall capacity multiplied by the operating voltage. As an example, commonly available Li-ion batteries may have a power density of approximately 250 watts per kilogram (W/kg).

The characteristics of the electrolyte may limit the highest operating temperature that a battery can withstand because the electrolyte vapor pressure may become too high to be contained within a conventional Li-ion battery shell. Similarly, the freezing temperature and electrical resistance of the electrolyte influence the battery's voltage and lowest operating temperature because these quantities affect temperature and vapor pressure of the battery during operation. Typical electrolytes limit the operating conditions of a Li-ion battery to between the temperatures of approximately −40° C. and approximately 60° C., with a maximum voltage of approximately 5.1V.

### SUMMARY

A first embodiment of the present disclosure can include a method of fabricating an electrode for a solid-state battery, the method comprising: forming a conductive, lithium electroactive layer on a substrate; forming a plurality of electrode nanowires on the conductive, lithium electroactive layer; and lithiating the plurality of electrode nanowires to yield a plurality of lithiated electrode nanowires.

A second embodiment of the present disclosure can include a method of fabricating a solid-state battery, the method comprising: forming a conductive, lithium electroactive layer on a substrate; forming a plurality of anode nanowires on the conductive, lithium electroactive layer; lithiating the plurality of anode nanowires to yield a plurality of lithiated anode nanowires; forming a solid electrolyte layer on the conductive, lithium electroactive layer; forming a cathode layer on the solid electrolyte layer; and forming a cathode current collector on the cathode layer.

A third embodiment of the present disclosure can include an electrode for a solid-state battery, the electrode comprising: a current collector region including a conductive, lithium electroactive material; and a plurality of nanowires contacting the current collector region.

A fourth embodiment of the present disclosure can include a solid-state battery comprising: an anode electrode structure including: an anode current collector including a conductive, lithium electroactive material; and a plurality of anode nanowires contacting the anode current collector; a solid electrolyte contacting the anode electrode structure, wherein the solid electrolyte is configured to transport lithium ions; a cathode electrode contacting the solid electrolyte; and a cathode current collector contacting the cathode electrode.

A fifth embodiment of the present disclosure can include a solid-state battery comprising: an anode electrode structure including: an anode current collector including a conductive, lithium electroactive material; and a plurality of anode nanowires contacting the anode current collector, wherein each of the plurality of anode nanowires includes lithium oxide, silicon, and a metal; a solid electrolyte contacting the anode electrode structure, wherein the solid electrolyte is configured to transport lithium ions; a cathode electrode contacting the solid electrolyte, wherein the cathode electrode includes lithium fluoride; and a cathode current collector contacting the cathode electrode, wherein the cathode current collector and the cathode electrode each include a common metal.

### BRIEF DESCRIPTION OF THE SEVERAL VIEWS OF THE DRAWINGS

FIGS. 1-3 depict cross-sectional views of a solid-state battery electrode being fabricated in processes according to various embodiments of the present disclosure.

FIG. 4 is a SEM photograph of an example conductive, lithium electroactive layer with electrode nanowires.

FIGS. 4-6 depict cross-sectional views of a solid-state battery electrode and solid-state battery being fabricated in processes according to various embodiments of the present disclosure.

FIG. 8 is a SEM photograph of an example cathode electrode according to an embodiment of the present disclosure.

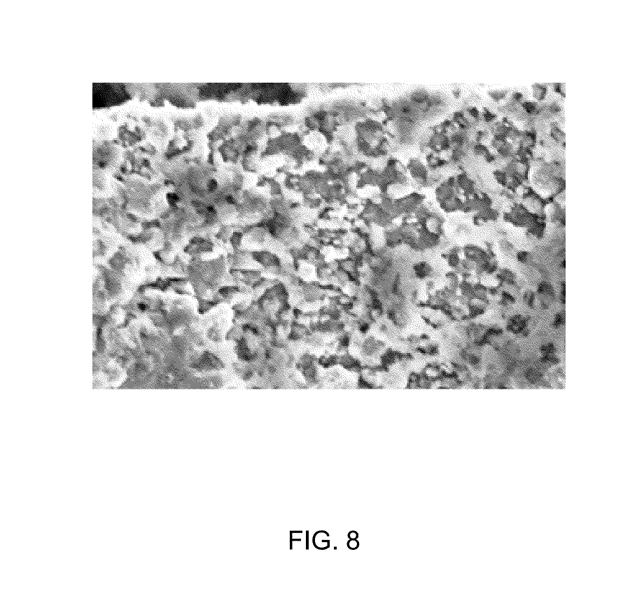

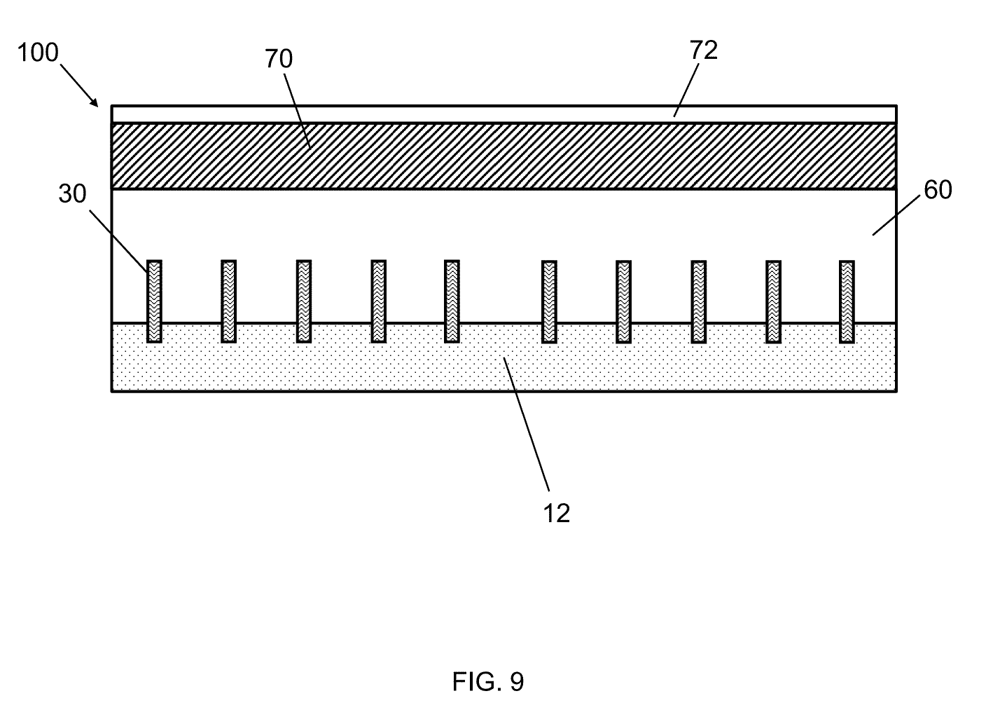

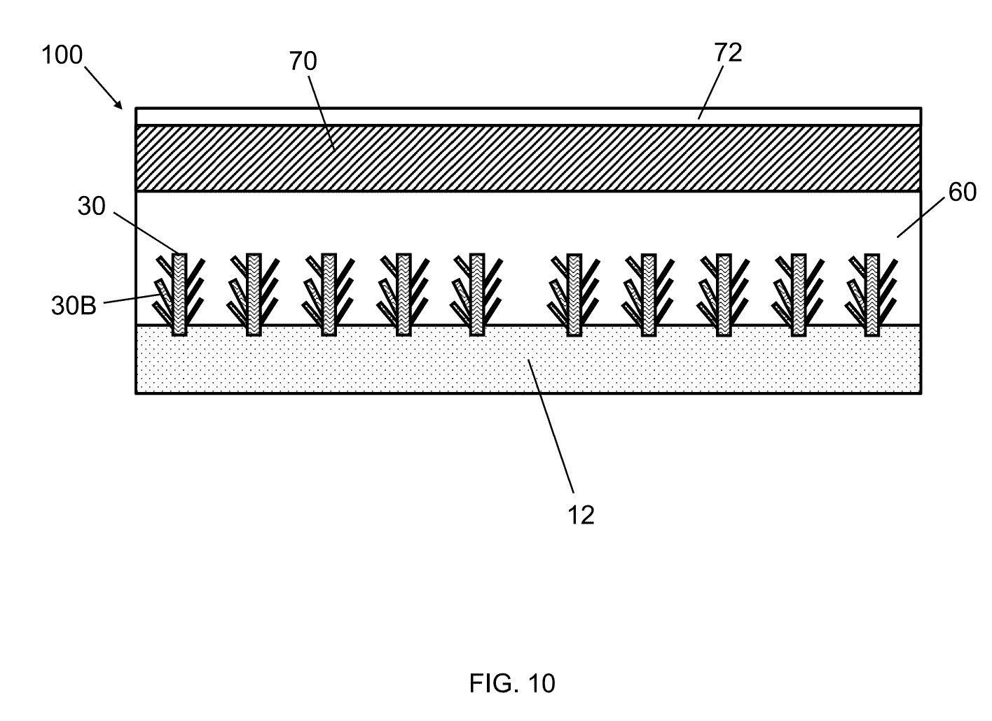

FIGS. 7-8 show cross-sectional views of a solid-state battery according to an embodiment of the present disclosure.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

In the following description, reference is made to the accompanying drawings that form a part thereof, and in which is shown by way of illustration specific exemplary embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

A solid-state battery and methods of fabrication are disclosed. An electrode of the solid-state battery can include a current collector region composed of a conductive, lithium electroactive material. A plurality of electrode nanowires may be in contact with the current collector region. In addition, a solid-state battery may be composed of an anode electrode structure, including an anode current collector composed of a conductive, lithium electroactive material, and several anode nanowires contacting the anode current collector. In addition, the solid-state battery can include a solid electrolyte, configured to transport lithium ions, contacting the anode electrode structure. The solid-state battery can also have a cathode electrode in contact with the solid electrolyte and a corresponding cathode current collector in contact with the cathode electrode. The structures of FIG. 9 and FIG. 10, discussed elsewhere herein, are embodiments of a solid-state battery according to the present disclosure.

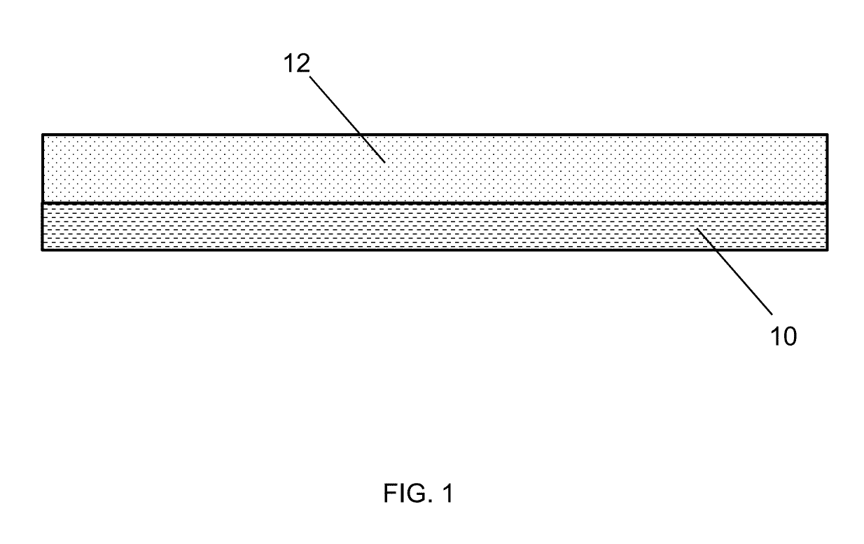

Referring now to FIG. 1, a process according to an embodiment of the present disclosure is shown. A method of fabricating an electrode for a solid-state battery can include forming a conductive, lithium electroactive layer on a substrate. Similar to methods used to fabricate logic chips, a solid-state battery can be fabricated on the surface of a reusable substrate 10. Materials (e.g., metals and alloys) which can be used for substrate 10 can include, but are not limited to, silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity).

A conductive, lithium electroactive layer 12 can be formed on substrate 10. Conductive, lithium electroactive layer 12 can generally be composed of any material capable of accepting lithium ions and functioning as a current collector. For example, conductive, lithium electroactive layer 12 may be in the form of an electrodeposited, highly conductive layer that will act as both a current collector and an anode power-delivery material. Lithium electroactive layer 12 may have a porous chemical composition, which may allow a large number of lithium ions to be embedded therein as compared to other electrode and current collector materials. In an embodiment, conductive, lithium electroactive layer 12 can be composed of one or more carbon nanotubes, molybdenum disulfide, and/or a layer of reduced graphene oxide (RGO). RGO in particular offers a reversible energy capacity of approximately 900 mAh/g for over 1,000 continuous charge/discharge cycles, and stable performance at up to approximately 150 C charging rates. As described herein, a charge rate unit of “C” indicates the length of time needed to charge the battery at a given rate, relative to the battery's lifetime after being fully charged. For example, a charge rate of “1 C” would charge a battery to full capacity after the same length of time needed to discharge the battery from full capacity. As another example, a fully charged battery may last for approximately ten hours per charge, but would reach full capacity after being charged at a rate of 10 C for approximately one hour.

In an embodiment where RGO is used in conductive, lithium electroactive layer 12, the RGO material can be formed with additional processes. For example, substrate 10 can be contacted with a graphene oxide (GO) media, which may for example be initially liquidous and in the form of a solution. The GO media can then be solidified by being subjected to a voltage over time. For example, a DC electric field of approximately 10 volts (V) can be applied to the GO media over a timespan of approximately ten to sixty minutes. The GO media can be dried into a solid state. For example, the GO media can be dried, for example, using a vacuum or subjecting the GO media to a temperature of approximately 50° C. for approximately sixty minutes. In other embodiments, the GO media of conductive, lithium electroactive layer 12 can be deposited or formed according to any currently known or later developed process.

To increase the specific surface area of the solution and form lithium electroactive pores, the GO media may be “reduced” to at least partially extract oxygen particles from the GO media. In general, oxygen can be extracted from the GO media via being briefly exposed to an energy pulse. The GO media can be reduced, for example, through a photo-induced “light-shine process,” which may include for example a strong pulse of light (e.g., a xenon flash pulse) with an energy of, e.g., between approximately 200 Watt seconds (Ws) and approximately 350 Ws. Generally, light-shine processes for reducing the GO media can include pulses which deliver sufficient power to reduce carbon-oxygen bonds in the GO media and thereby create pores. In other embodiments, the solid GO media can be chemically reduced by exposing the solid GO media to a flowing hydrazine vapor, thermal annealing of the solid GO media in a hydrogen atmosphere, or by a combination of some or all of the processes described herein. In addition, other currently known or later developed processes (e.g., acid reduction, laser reduction, microwave reduction, thermal heating or annealing, and combinations thereof) can be used to at least partially extract oxygen from the GO media. The carbon-to-oxygen ratio of RGO making up resulting conductive, lithium electroactive layer 12 can be between, for example, approximately 15:1 and 16:1, with a minimum thickness of approximately 3-4 micrometers (μm) and up to, for example, approximately 200 μm. RGO can offer high lithium electroactivity through its porous structure, as well as a resistivity of approximately 100 kilohms (kΩ) or less. In addition, the lithium energy capacity of RGO may exceed 500 milliamp hours per gram (mAh/g) at charge rates of approximately C/2. RGO in conductive, lithium electroactive layer 12 may have, for example, a reversible energy capacity of approximately 900 mAh/g for over 1,000 continuous charge/discharge cycles, and may provide stable performance at up to approximately 150 C charge rates.

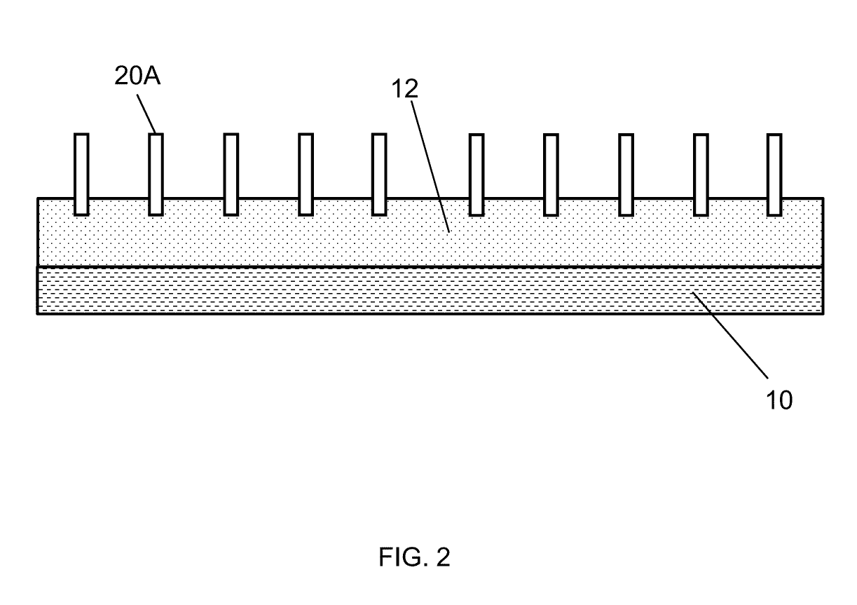

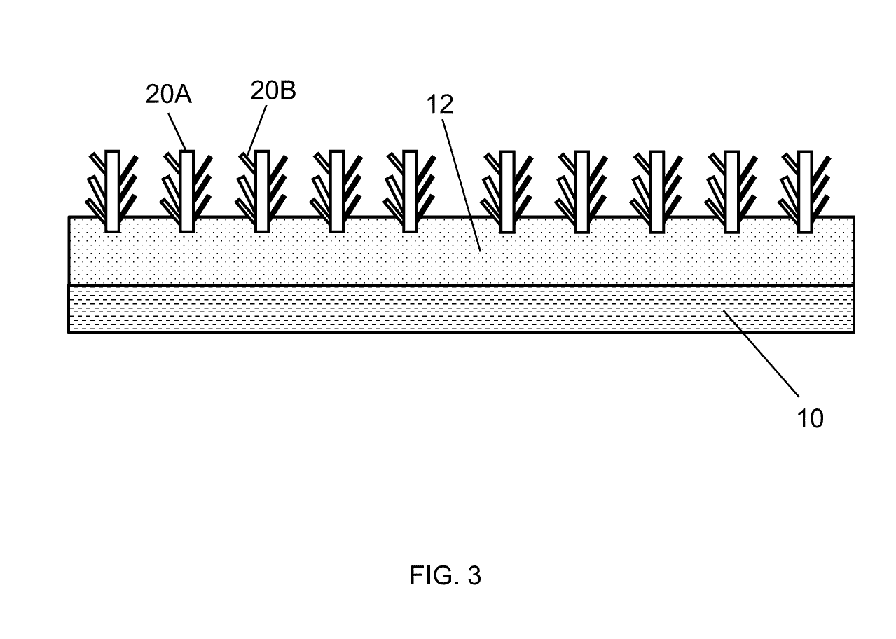

As shown in FIG. 2 and FIG. 3, embodiments of the present disclosure can include forming a plurality of electrode nanowires 20A, 20B on conductive, lithium electroactive layer 12. Electrode nanowires 20A, 20B can function as an electrode (e.g., an anode) material, and may be composed of, for example a Ni—Li₂O—Si mixture. In general, electrode nanowires 20A, 20B can be composed of metal-LiₓO_{y}—Si mixtures. Li₂O (lithium oxide) has a relatively favorable gravimetric capacity, and Ni (Nickel) provides high electron conductivity. The use of Si (silicon) can increase the capacity of electrode nanowires 20A, 20B and therefore increase the electrode's range of operating voltages or “voltage window,” since the reduction of Li from Li₂O in the presence of Ni occurs at a high voltage of approximately 1.2-1.5 V. The Li₂O in the anode can reduce the need for Li in the electrolyte and create a stable, reversible solid electrolyte interface (SEI) layer, independent of the corresponding electrolyte. Electrode nanowires 20A, 20B composed of Ni—Li₂O—Si have demonstrated capacities of, for example, approximately 1000 mAh/g for over 1,000 charge/discharge cycles, and cycle stability at charge rates as high as 10 C. This material can also withstand high temperatures, and may be limited only by the melting temperature of Li₂O, which is approximately 600° C.

Electrode nanowires 20A, 20B can, as an example, be deposited onto the surface of conductive, lithium electroactive layer 12. As used herein, the term “depositing” may include any now known or later developed technique appropriate for deposition, including but not limited to, for example: chemical vapor deposition (CVD), low-pressure CVD (LPCVD), plasma-enhanced CVD (PECVD), semi-atmosphere CVD (SACVD), high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, laser assisted deposition, thermal oxidation, spin-on methods, physical vapor deposition (PVD), glancing low angle deposition (GLAD), chemical oxidation, molecular beam epitaxy (MBE), plating, and evaporation. The formation of electrode nanowires 20A, 20B can be substantially similar to processes described in U.S. P.G. Pub. 2013/0143124, which is incorporated herein by reference. In some embodiments, the forming or depositing of electrode nanowires 20A, 20B can be achieved by using PVD to deposit a conductive metal, between approximately 50-150 nanometers (nm) in thickness. The conductive metal may be composed of, for example, nickel, copper, or other metals with a greater Gibbs Free Energy change during oxidation than silicon (i.e., any metal other than titanium, aluminum, calcium, and magnesium). In some embodiments, the deposited conductive metal may be composed of a refractory and/or a non-refractory transition metal. As used herein, a “transition metal” may include metals with valence electrons in two atomic energy levels instead of only one, such as metals from groups three through twelve of the periodic table. Forming electrode nanowires 20A, 20B with PVD can offer a fabricator some control over the size and shape of electrode nanowries 20A, 20B. To prepare for the formative reactions, oxygen can be extracted from the layer (e.g., by vacuuming), and the metal can be heated. In an embodiment, the metal may be heated to, for example, approximately 850° C., optionally in the presence of a non-reactive or inert gas (e.g., an argon atmosphere) to reduce burning of the heated metal. The heated metal can then be contacted with a pressurized, silicon-containing mixture. Silicon from the pressurized, silicon-containing mixture can react and combine with metal under the increased temperature. The reaction can be accelerated by increasing the pressure of the mixture. In an embodiment, the metal may be exposed to a mixture of SiH₄ (silane) or a silicon precursor compound for, e.g., approximately 120 minutes, with the pressure of the mixture between, e.g., approximately 6.5 kPa and 8.0 kPa. Following the introduction of silicon to the metal, the metal may be returned to room temperature, and the mixture may be pumped away from conductive, lithium electroactive layer 12. This reaction can cause electrode nanowires 20A, 20B to form on, and in some cases generally project from conductive, lithium electroactive layer 12. In addition, the formed electrode nanowires 20A, 20B can have a thickness of, for example, 150 nm or less.

In a first process, electrode nanowires 20A are formed with subsequent processes by adding more electrode nanowires 20B (FIG. 3) as “branch” nanowires. The formed electrode nanowires 20A may remain inert during the forming of additional electrode nanowires 20B, which may protrude from the structure of other electrode nanowires 20A as “branch” nanowires, as shown by example in FIG. 3. Repeating the process of forming electrode nanowires 20A, 20B can therefore cause the specific surface area of electrode nanowires 20A, 20B to increase with each repetition. In addition, electrode nanowires 20A, 20B can be formed according to any currently known or later developed process of fabricating micro- or nano-electronic structures and/or wires. Electrode nanowires 20A, 20B yielded from a process according to the present disclosure can accommodate charge rates up to, e.g., approximately 10 C, and can maintain their structural integrity over more than, e.g., one thousand charge cycles.

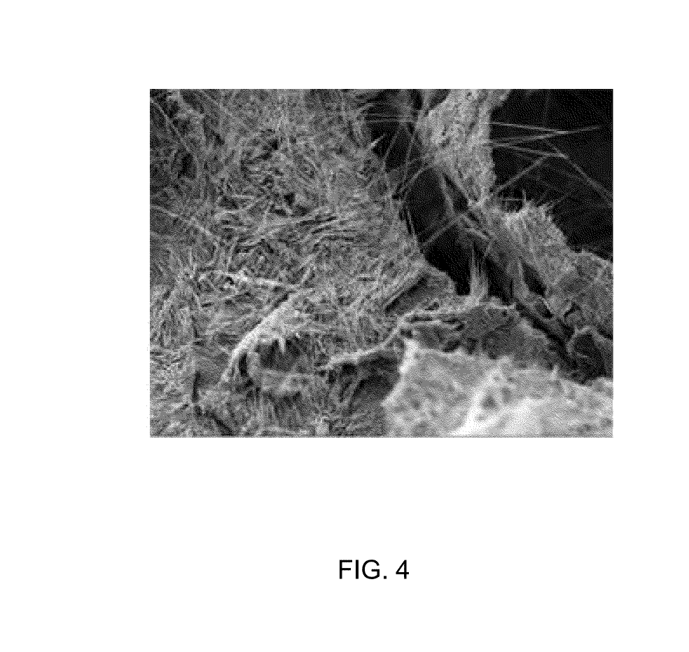

Turning to FIG. 4, an example scanning electron microscope (SEM) photograph of conductive, lithium electroactive layer 12 (FIGS. 1-3) with electrode nanowires 20A, 20B (FIGS. 2-3) is shown for the purposes of clarity. As indicated in FIG. 4, electrode nanowires 20A, 20B may project from lithium electroactive layer 12 in a random, disorganized fashion, with some electrode nanowires 20A, 20B crossing over others. Further, the surface of conductive, lithium electroactive layer 12 may have a complex geometry with many peaks, valleys, etc.

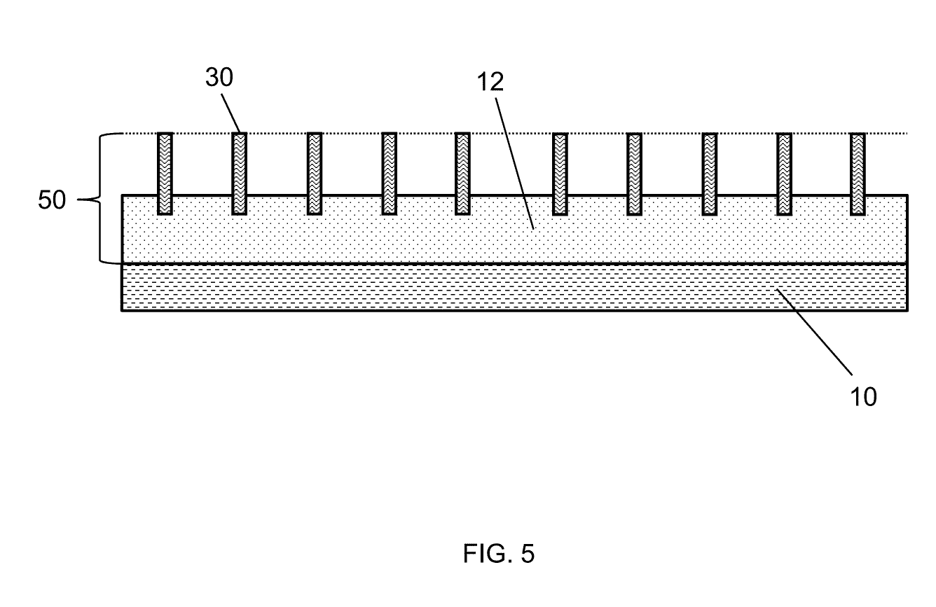

Turning to FIG. 5, an embodiment of the present disclosure can also include lithiating the electrode nanowires 20A, 20B (FIGS. 2, 3) to yield lithiated electrode nanowires 30. In FIGS. 5-7 and 8, the branching electrode nanowires 20B have been removed for the sake of clarity. However, it is understand that processes according to the present disclosure can be applied in circumstances where branched nanowires have been formed and lithiated. Lithiated electrode nanowires 30 and conductive, lithium electroactive layer 12 together form a solid-state battery electrode 50 capable of being used to charge and discharge electricity, for example, in a Li-ion battery. One manner of lithiating electrode nanowires 20A, 20B (FIGS. 2, 3) to form lithiated electrode nanowires 30 is to deposit lithium onto electrode nanowires 20A, 20B (FIGS. 2, 3). More specifically, lithium can be deposited during the same process used to form electrode nanowires 20A, 20B (FIGS. 2, 3), e.g., by co-depositing lithium with another metal. In an alternative embodiment, the formed electrode nanowires 20A, 20B (FIGS. 2, 3) can be lithiated by being contacted with a lithium-rich electrolyte (e.g., LiPF₆), and then subjected to a voltage to yield lithiated electrode nanowires 30. In yet another embodiment, lithium can be formed or deposited onto electrode nanowires 20A, 20B (FIGS. 2, 3) as part of a solid “lithium layer,” and then subjected to a metallurgical process, such as annealing, to create lithiated electrode nanowires 30. A “lithium layer,” as used herein, may include a layer of material composed entirely of lithium in addition to layers of material which may at least partially include lithium (e.g., lithium-rich materials and substances). In an embodiment, lithiated electrode nanowires 30 can be composed of a metal (e.g., nickel or copper), lithium oxide (Li₂O), and silicon.

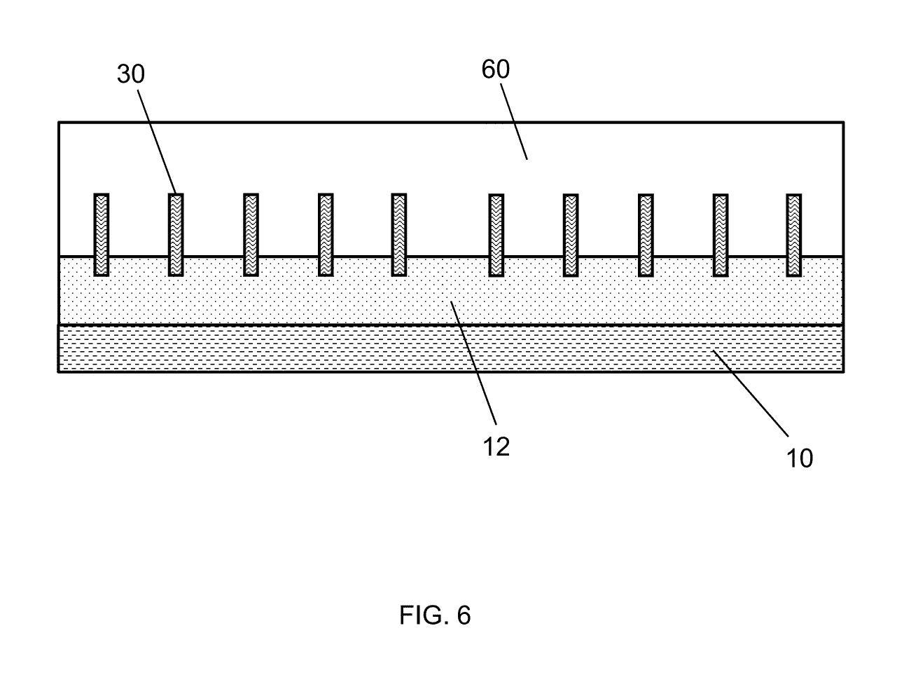

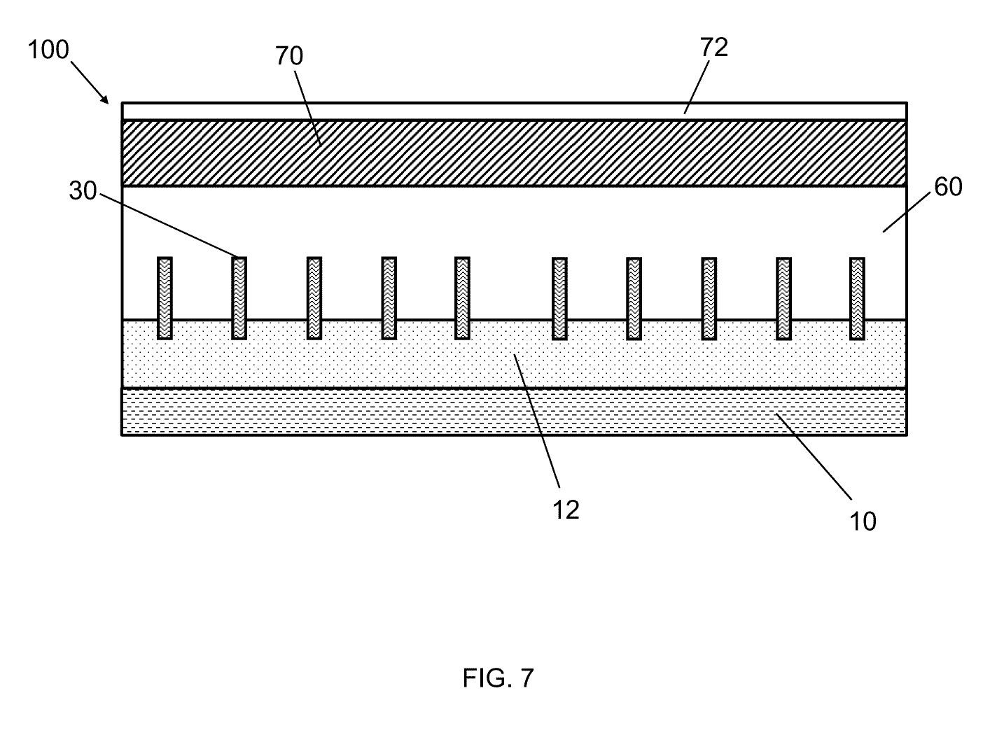

The resulting solid-state battery electrode 50 may undergo additional processes to form a solid-state battery. Turning now to FIG. 6, a process of forming a solid electrolyte layer 60 on conductive, lithium electroactive layer 12 is shown. Solid electrolyte layer 60 may be composed of any currently known or later developed material capable of selectively transporting lithium ions while otherwise being electrically insulative. In an embodiment, solid electrolyte layer 60 may be a layer of lithium polyoxide nitride (LiPON). The use of LiPON in solid electrolyte layer 60 avoids the use of a separator between the electrode and the electrolyte, and does not require further application of liquid solvents found in conventional batteries. In addition, the structure of conductive, lithium electroactive layer 12 and lithiated electrode nanowires 30 increases the geometric complexity of solid electrolyte layer 60, which reduces the appearance of structural defects (e.g., pinholes) therein. LiPON can also improve the thermal capabilities of the battery, since theoretical breakdown voltage of LiPON is approximately 7.5V and its melting temperature is approximately 1100° C.

Turning to FIG. 7, another process according to an embodiment of the present disclosure is shown. A cathode layer 70 can be formed on a surface of solid electrolyte layer 60. Cathode layer 70 can be formed, e.g., by co-sputtering LiF with a metal, thermally evaporating lithium fluoride and copper to form Cu—LiF, and/or depositing a fine metal and forming a reversible fluoride from the deposited metal. Generally, cathode layer 70 can be composed of LiF and a metal, e.g., lithium fluoride-copper (Cu—LiF). LiF generally offers a voltage window of, e.g., at least 4 V. In addition, cathode layer 70 with LiF can offer a specific capacity between, e.g., approximately 680 mAh/g and approximately 2200 mAh/g, based on the reversible displacement reaction:

Cu+LiF→xLi⁺+xe⁻+Li₁₋ₓF₁₋ₓ+CuFₓ.

Cathode layer 70 with LiF—Cu can offer a specific capacity of up to, e.g., approximately 1200 mAh/g with a coulombic efficiency of, e.g., approximately 99.5%. Cathode layer 70 may have a thickness of, for example, 5 μm or less. In addition, cathode layer 70 may offer an average reversible capacity of, e.g., approximately 860 mAh/g, which is approximately five times greater than the reversible capacity of conventional cathodes. The resulting energy density of cathode layer 70 composed of Cu—LiF may be as high as, e.g., approximately 550 Wh/kg. Cathode layer 70 can also withstand high temperatures, with the melting temperature of LiF (approximately 900° C.) being the limiting factor. A cathode current collector 72 can be formed on cathode layer 70. Cathode current collector 72 and any accompanying electrical connectors can be deposited, e.g., via copper sputtering or electro-deposition, which are both known processes in the art of semiconductor fabrication. The resulting structure is a solid-state battery 100 with the advantages and properties described herein. A SEM photograph of an example cathode layer 70 composed of Cu—LiF is shown by example in FIG. 8 for the purposes of clarity.

Turning to FIG. 9, an embodiment of solid-state battery 100 without substrate 10 (FIGS. 1-7) is shown. In an embodiment, substrate 10 can be removed from solid-state battery 100 through any currently known or later developed removal processes, such as delamination or shear stress removal. Although substrate 10 is shown to be absent from FIG. 9, it is understood that substrate 10 may be removed at various other points during the formation of solid-state battery 100, including any process following the formation of conductive, lithium electroactive layer 12. Following the removal of substrate 10, solid-state battery 100 can be implemented in an electronic circuit by electrically coupling conductive, lithium electroactive layer 12 to current-carrying components.

As shown in FIG. 9, solid-state battery 100 may have particular structural features. Solid-state battery 100 may include an anode electrode structure with an anode current collector in the form of conductive, lithium electroactive layer 12, and several electrode nanowires 20A, 20B (FIGS. 2, 3), which may be lithiated electrode nanowires 30, contacting the anode current collector. Each lithiated nanowire 30 may be composed of a mixture of lithium oxide, silicon, and a metal. A solid electrolyte layer 60, configured to transport lithium ions, may contact the anode electrode structure (e.g., lithiated electrode nanowires 30 and/or conductive, lithium electroactive layer 12) of solid-state battery 100. Additionally, cathode layer 70 can contact solid electrolyte layer 60, and cathode current collector 72 can contact cathode layer 70. In an embodiment, cathode layer 70 may be composed of lithium fluoride (LiF) and a conductive metal such as copper or aluminum, as discussed elsewhere herein. Furthermore, cathode layer 70 and cathode current collector 72 may each include a common conductive metal if desired. In an alternative embodiment, as shown in FIG. 10, lithiated electrode nanowires 30 can include branch nanowires 30B projecting therefrom.

Solid-state battery 100 can have a projected energy density of, e.g., at least 450 Wh/kg, accommodating charge rates of up to, e.g., approximately 150 C. Solid-state battery 100 may allow lithiated electrode nanowires 30 to be interspersed across conductive, lithium electroactive layer 12 to retain high power capabilities. For example, solid-state battery 100 may have over five times the power capability of conventional Li-ion batteries, with a corresponding reduction in ionic mobility. In addition, the ionic conductivity of solid electrolyte layer 60 in solid-state battery 100 can be less than a conventional liquid electrolyte layer. Solid electrolyte layer 60 thus allows solid-state battery 100 to be manufactured in accordance with semiconductor fabrication techniques, and significantly increases the operating temperature window (e.g., up to 600° C.) and/or the voltage window of solid-state battery 100 over conventional batteries. As a result, solid-state battery 100 need not include a thermal management system, as may be required in conventional batteries. The anode and cathode electrodes (e.g., conductive, lithium electroactive layer 12, lithiated electrode nanowires 30, cathode layer 70) may be pre-doped with Li in order to compensate for any Li deficiency of solid electrolyte layer 60. Solid electrolyte layer 60 can be deposited, e.g., by using chemical vapor deposition (CVD), physical vapor deposition (PVD) or atomic layer deposition (ALD).

The embodiments of apparatuses discussed in this disclosure can offer several technical and commercial advantages. One advantage of the present disclosure is the ability to integrate several advantageous material properties using semiconductor-compliant processes and equipment. Solid-state batteries 100 according to the present disclosure may be created as a stack, in the same fashion as logic chips, on top of a substrate 10 such as a reusable silicon wafer. Solid-state battery 100 can have an energy density in excess of, e.g., 450 Wh/kg, and accommodate charge rates of up to, e.g., approximately 150 C. In operation, solid-state battery 100 is more cost effective than a conventional lithium manganese oxide graphite (LMO-G) battery. The disclosed methods of fabricating solid-state battery 100 may be more cost-effective than conventional methods by eliminating the cost of binders, separators, and overhead costs associated with conventional electrode processing. In addition, embodiments of the present disclosure can also reduce the costs of cell assembly, direct labor/overhead, and other fabrication activities. Solid-state battery 100 can also reduce the need for external capacitors, and can be integrated with vehicle electronics.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. It will be further understood that the terms “comprises” and/or” comprising,” when used in this specification, specify the presence of stated features, integers, steps, operations, elements, and/or components, but do not preclude the presence or addition of one or more other features, integers, steps, operations, elements, components, and/or groups thereof.

This written description uses examples to disclose the invention, including the best mode, and to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A method of fabricating an electrode for a solid-state battery, the method comprising:
forming a conductive, lithium electroactive layer on a substrate;
forming a plurality of electrode nanowires on the conductive, lithium electroactive layer; and
lithiating the plurality of electrode nanowires to yield a plurality of lithiated electrode nanowires.

2. The method of claim 1, wherein the forming of the conductive, lithium electroactive layer includes:
contacting the substrate with a graphene oxide media (GO);
applying a voltage to the GO media;
drying the GO media; and
partially extracting oxygen from the GO media to form a reduced graphene oxide (RGO).

3. The method of claim 1, further comprising forming a plurality of branch nanowires on each of the plurality of electrode nanowires.

4. The method of claim 1, wherein the forming of the plurality of electrode nanowires includes:
forming a metal on the conductive, lithium electroactive layer;
heating the metal; and
contacting the heated metal with a pressurized mixture including silicon to form the plurality of electrode nanowires.

5. The method of claim 4, further comprising extracting oxygen from the metal.

6. The method of claim 1, wherein the lithiating includes depositing lithium during the forming of the plurality of electrode nanowires.

7. The method of claim 1, wherein the lithiating includes contacting the plurality of electrode nanowires with an electrolyte including lithium.
The method of claim 1, further comprising removing the substrate, following the forming of the conductive, lithium electroactive layer.

9. The method of claim 1, further comprising:
forming a solid electrolyte layer on the conductive, lithium electroactive layer;
forming a cathode layer on the solid electrolyte layer; and
forming a cathode current collector on the cathode layer.

10. The method of claim 9, wherein the forming of the cathode layer includes combining lithium fluoride with a metal.

11. The method of claim 9, wherein the forming of the solid electrolyte layer includes one of chemical vapor deposition (CVD), low-pressure CVD (LPCVD), plasma-enhanced CVD (PECVD), semi-atmosphere CVD (SACVD) high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, laser assisted deposition, thermal oxidation, spin-on methods, physical vapor deposition (PVD), glancing low angle deposition (GLAD), chemical oxidation, molecular beam epitaxy (MBE), and plating.

12. An electrode for a solid-state battery, the electrode comprising:
a current collector region including a conductive, lithium electroactive material; and
a plurality of nanowires contacting the current collector region.

13. The electrode of claim 12, wherein at least one of the plurality of nanowires projects from a surface of the current collector region.

14. The electrode of claim 12, wherein at least one of the plurality of nanowires includes silicon.

15. The electrode of claim 12, further comprising a plurality of branch nanowires contacting one of the plurality of nanowires.

16. The electrode of claim 15, wherein the plurality of branch nanowires includes silicon, lithium oxide, and a metal.

17. The electrode of claim 12, further comprising:
a solid electrolyte contacting the anode current collector and the plurality of anode nanowires, wherein the solid electrolyte is configured to transport lithium ions;
a cathode electrode contacting the solid electrolyte; and
a cathode current collector contacting the cathode electrode.

18. The electrode of claim 17, wherein the solid electrolyte comprises lithium polyoxide nitride (LiPON).

19. The electrode of claim 17, wherein the cathode electrode includes lithium fluoride.

20. A solid-state battery comprising:
an anode electrode structure including:
an anode current collector including a conductive, lithium electroactive material; and
a plurality of anode nanowires contacting the anode current collector,
wherein each of the plurality of anode nanowires includes lithium oxide, silicon, and a metal;
a solid electrolyte contacting the anode electrode structure, wherein the solid electrolyte is configured to transport lithium ions;
a cathode electrode contacting the solid electrolyte, wherein the cathode electrode includes lithium fluoride; and
a cathode current collector contacting the cathode electrode, wherein the cathode current collector and the cathode electrode each include a common metal.
